(19) United States
(12) Patent Application Publication
(10) Pub. No.: US 2025/0338450 A1
(43) Pub. Date: Oct. 30, 2025

(54) HIGH-EFFICIENCY PRECOOLING SYSTEM FOR A DATA CENTER

(71) Applicants: Bradley John Klein, Chonburi (TN); Nicholas Ben Barrowclough, Porac (PH)

(72) Inventors: Bradley John Klein, Chonburi (TN); Nicholas Ben Barrowclough, Porac (PH)

(21) Appl. No.: 18/651,600

(22) Filed: Apr. 30, 2024

(51) Int. Cl. H05K 7/20

(52) U.S. Cl. CPC H05K 7/20609; H05K 7/20145; H05K 7/20272; H05K 7/207; H05K 7/20736; H05K 7/20781

(57) ABSTRACT

A precooling system for a data center comprises a containment structure configured to direct warm air coming out of the back side of a computer rack into the first inlet of a first heat exchanger. Circulating fluid in the first heat exchanger is used to cool the air before releasing it toward the recirculation on the other side of the computer rack so as to air-cool the computer equipment inside the computer rack. A second heat exchanger may be used to cool the returning warm fluid. The second air inlet and the second air outlet of the second heat exchanger may be located outside the data center. The precooling system may be used in addition to a conventional air conditioning system to service the data center so as to reduce the energy consumption required to keep the data center at the optimal temperature.

### BACKGROUND

Without limiting the scope of the invention, its background is described in connection with cooling systems. More particularly, the invention describes a cooling system for a computer data center, which is capable of providing air cooling to computer racks with high efficiency and flexible operation depending on ambient conditions.

The problem of heat generation in large, enclosed data centers, which arises from operating multiple computers simultaneously, is a critical issue that affects the efficiency, longevity, and operational costs of these facilities. Data centers, crucial hubs for storing, processing, and disseminating vast amounts of digital information, house numerous servers and other computing hardware that inherently produce significant amounts of heat during operation. This heat generation is primarily due to the electrical power consumed by the servers, which, when converted into energy to run computational tasks, also releases heat as a byproduct. As more servers are packed into a data center to handle increasing data demands, the cumulative heat produced can escalate rapidly.

This concentrated heat generation can lead to elevated temperatures within the data center, which, if not properly managed, can surpass the optimal operating conditions recommended for electronic hardware. High temperatures can degrade the performance of servers, increase the likelihood of hardware failures, and shorten the lifespan of the equipment. Furthermore, the need to cool these environments to maintain safe operating temperatures leads to significant energy consumption through cooling systems like air conditioners and chillers, which in turn increases operational costs and can have a detrimental environmental impact due to increased carbon emissions.

Managing this heat effectively is therefore not only critical for maintaining system reliability and performance but also for achieving energy efficiency and reducing the environmental footprint of data centers. The implementation of advanced cooling techniques, strategic data center layout design, and the adoption of energy-efficient technologies are among the approaches employed to tackle the heat management challenges in modern data centers.

Conventional air conditioning is one of the primary methods used to cool large data centers, alongside a variety of innovative cooling approaches designed to enhance efficiency and sustainability. The conventional method typically involves the use of Computer Room Air Conditioning (CRAC) units or Computer Room Air Handlers (CRAH) units. These systems regulate the temperature and humidity in the data center by circulating chilled air. Air is drawn in, cooled by refrigerants or chilled water in heat exchangers, and then distributed throughout the data center to absorb heat emitted by servers and other equipment. This warm air is then cycled back to the CRAC or CRAH units to be re-cooled and recirculated.

In addition to conventional air conditioning, alternative, and supplementary cooling strategies are also employed to manage heat in data centers more effectively. One such approach is the use of in-row cooling, where cooling units are placed directly between server racks. This setup minimizes the distance cold air must travel before reaching the servers, improving cooling efficiency and reducing the mixing of hot and cold air streams.

Another innovative method is hot aisle/cold aisle configuration, which organizes computer racks 5 in alternating rows with their backs facing each other, creating hot aisles 10 and cold aisles 15. One example is illustrated in FIG. 2. Warm air goes up to the ceiling plenum 18 and from there is recirculated by an air pump 17 through the built-in chiller of the air conditioning system to enter a sub-floor space 19, before entering cold aisles 15. This configuration helps to manage airflow more predictably by confining and extracting the warm air emitted from the servers more efficiently.

For more sustainable options, some data centers utilize free cooling systems, which leverage external environmental conditions to aid in cooling. When the outside temperature is sufficiently low, outside air can be brought in to cool the facility, significantly reducing the reliance on mechanical cooling and thereby lowering energy consumption. Advanced versions of this technique include the use of economizers, which can switch between outside air and refrigeration-based cooling depending on the external weather conditions. Additionally, liquid cooling is a rapidly emerging technique that involves using water or other liquids in direct contact with components to absorb heat more effectively than air, which is particularly useful in high-density configurations where traditional air cooling is insufficient. These diverse cooling methodologies illustrate the dynamic and evolving nature of data center thermal management, reflecting ongoing efforts to maintain operational efficiency while minimizing environmental impact. They also highlight an unmet need for a more efficient system that requires minimal operational cost while reducing energy consumption for the data center cooling systems.

Modern cooling systems for data centers, while effective in managing the substantial heat generated by servers and other computing equipment, come with several disadvantages:
High Energy Consumption: Traditional cooling systems, particularly those reliant on air conditioning, consume a significant amount of energy. This is not only costly but also environmentally impactful, as data centers already account for a substantial portion of global electricity use. Cooling systems can sometimes consume as much energy as the IT equipment they are meant to cool, leading to high operational costs and a large carbon footprint;
Complex Infrastructure and Maintenance: Modern cooling systems often involve complex infrastructure, including chillers, air handlers, and specialized plumbing for liquid cooling systems. This complexity requires regular maintenance and monitoring to ensure optimal performance and prevent failures. The initial setup and ongoing maintenance of these systems require skilled technicians, adding to operational costs;
Need to Filter Outside Air: even in cases when outside air is cooler than the air inside the data center, there is a risk of encountering dust, dirt, soot, and other contaminants when using outside air for air cooling of the computer components. A significant investment may be required to equip the data center with a high-quality air filtration system to remove these contaminants from the air prior to circulating the air through the computer racks. One such system is shown in FIG. 3 in which warm air is partially or fully exhausted outside the data center (arrow 61), and fresh air is introduced into the sub-floor space 19 (arrow 63) to mix with the inside air (arrow 62);
Need to Control Humidity of Outside Air: The use of outside air for direct air cooling is fraught with the risks caused by improper and uncontrolled humidity of the outside air. The humidity of the outside air must be maintained within a certain predefined range before that air can be allowed to enter the server's air inlet. If the humidity is too high, it could cause condensation. High humidity would also lead to the formation of hygrometric dust particles, which make dust in the air more likely to stick to electrical components in the computer. This, in turn, can reduce heat transfer and even cause corrosion of those components. If the humidity is too low, it could lead to electrostatic discharge (ESD). Treating the air by either adding or removing humidity is an expensive and environmentally unfriendly process;
Limited Scalability and Flexibility: As data centers grow and evolve, scaling traditional cooling systems can be challenging. Expanding these systems often involves significant disruption and investment. Furthermore, rigid infrastructures like ductwork and piping can limit the flexibility needed for reconfiguring server layouts as technology and demand change;
Environmental Impact: Besides high energy consumption, some cooling systems still use refrigerants that can be harmful to the environment. Although newer systems use more eco-friendly refrigerants, issues such as leaks can still pose risks to the environment;
Water Usage: Many modern cooling techniques, including liquid cooling and certain types of free cooling, rely heavily on the availability of running water. This can be a significant drawback in areas where water is scarce, posing sustainability concerns and necessitating the use of additional resources for water management;
Potential for System Failure: With the complexity of modern cooling systems, there is a heightened risk of system failure. A malfunction in one part of the cooling system can lead to overheating, which might result in downtime and potential damage to expensive IT equipment.

There is a need, therefore, for a novel cooling system that resolves at least some or all of the drawbacks listed above and provides for high-efficiency cooling of the data centers regardless of their size, location, and surrounding conditions.

### SUMMARY

Accordingly, it is an object of the present invention to overcome these and other drawbacks of the prior art by providing a novel precooling system for a data center that is configured to extract as much heat from the air passing through as possible without using air conditioning.

It is another object of the present invention to provide a precooling system for a data center configured to utilize cooler air outside the computer racks to reduce the temperature of the air used for air cooling of the computer racks.

It is a further object of the present invention to provide a precooling system for a data center configured for a seamless introduction to and operating concurrently with a conventional air cooling system that may already be in use in a data center.

It is yet a further object of the present invention to provide a precooling system for a data center that reduces energy and water consumption while operating thereof.

A precooling system for a data center, according to some embodiments of the present invention, may be provided as a supplementary system for use with a conventional cooling system to reduce overall energy consumption. In other embodiments, the precooling system may be the sole cooling system for a data center, depending on the ambient conditions. The data center may include an enclosure with a containment structure located therein. At least one or more computer racks may be placed within or to form the containment structure, including forming an enclosed containment space therein. The precooling system may include a first heat exchanger and a second heat exchanger.

The first heat exchanger may be described as having a first air inlet and a first air outlet. The first air inlet may be adapted to accept air from the enclosed containment space. The first heat exchanger may further include a first plurality of heat-exchanging fluid passages that may be configured to extract heat from the air passing from the first air inlet to the first air outlet, thereby cooling thereof. The heat from the passing air may be extracted into the fluid circulating through the first plurality of fluid passages. Slightly negative air pressure (below ambient air pressure) may be maintained at the first air inlet so as to urge air to enter the first air inlet.

The second heat exchanger may have a second air inlet and a second air outlet, both may be configured to respectively accept and exhaust air outside the enclosure or the containment structure of the data center. A second plurality of heat-exchanging fluid passages may also be provided and configured to extract heat from the fluid circulating therethrough, thereby cooling the passing fluid. A fluid pump may be adapted to circulate the fluid between the first heat exchanger and the second heat exchanger.

The precooling system, therefore, may be configured to use the containment structure as a way to direct airflow to pass through the first heat exchanger and then circulate through the computer rack in order to air cool computers thereof, before flowing back into the enclosed containment space.

Further embodiments and configurations describe other ways to circulate and cool the hot air emanating from the computer racks using the advantageous temperature differential between the hot exhaust air after passing through the computer rack and cooler ambient air inside or outside the enclosed data center.

A control system with sensors monitoring air temperature in various locations inside and outside the data center may also be provided and configured to adjust or switch air circulation patterns depending on the changing ambient and internal conditions.

### BRIEF DESCRIPTION OF THE DRAWINGS

Subject matter is particularly pointed out and distinctly claimed in the concluding portion of the specification. The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 is a general view of a row of computer racks within an enclosed data center,

FIG. 2 is a diagram of the operation of a conventional heat exchanger of the prior art,

FIG. 3 is a diagram of the operation of another conventional heat exchanger of the prior art,

FIG. 4 is a diagram of operation of the first heat exchanger and a second heat exchanger of the present invention,

FIG. 5 is a perspective side view of an exemplary passive multi-stage heat exchanger,

FIG. 6 is a perspective side view of an exemplary multi-stage heat exchanger equipped with air pumps to increase air circulation therethrough,

FIG. 7 is an exemplary perspective side view of the heat-exchanging fins inside the heat exchanger,

FIG. 8 is a general perspective view of a containment structure enclosing at least one computer rack,

FIG. 9 is a schematic diagram of the first embodiment of the present invention showing air circulation patterns therethrough,

FIG. 10 is a schematic diagram of the second embodiment of the present invention showing air circulation patterns therethrough,

FIG. 11 is a schematic diagram of the third embodiment of the present invention showing air circulation patterns therethrough,

FIG. 12 is a schematic diagram of the fourth embodiment of the present invention showing air circulation patterns therethrough,

FIG. 13 is a schematic diagram of the fifth embodiment of the present invention showing air circulation patterns therethrough,

FIG. 14 is a schematic diagram of the sixth embodiment of the present invention showing air circulation patterns therethrough,

FIG. 15 is a schematic diagram of the seventh embodiment of the present invention showing air circulation patterns therethrough,

FIG. 16 is a schematic diagram of the eighth embodiment of the present invention showing air circulation patterns therethrough,

FIG. 17 is a schematic diagram of the nineth embodiment of the present invention showing air circulation patterns therethrough, and

FIG. 18 is a schematic diagram of the tenth embodiment of the present invention showing air circulation patterns therethrough.

### DETAILED DESCRIPTION OF PREFERRED EMBODIMENTS OF THE INVENTION

The following description sets forth various examples along with specific details to provide a thorough understanding of claimed subject matter. It will be understood by those skilled in the art, however, that claimed subject matter may be practiced without one or more of the specific details disclosed herein. Further, in some circumstances, well-known methods, procedures, systems, components and/or circuits have not been described in detail in order to avoid unnecessarily obscuring claimed subject matter. In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

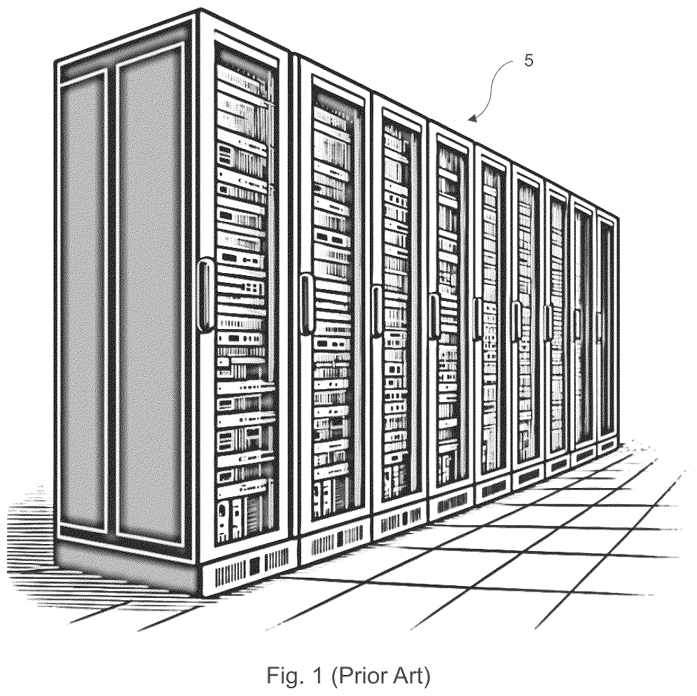

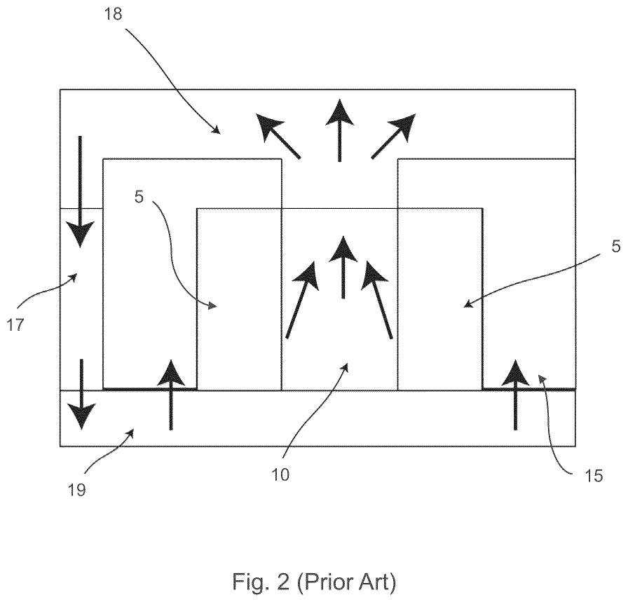

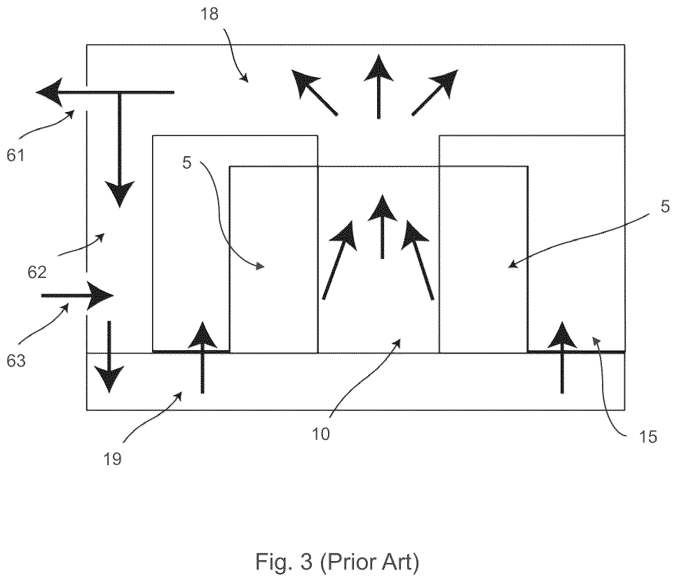

A data center is generally organized to optimize space and enhance the efficiency of air circulation, power distribution, and data connectivity. The typical layout consists of rows of computer racks 5, such as the one seen in FIG. 1, which may be arranged in a grid-like pattern. These computer racks, standing usually about six feet tall, are designed to house servers, storage systems, and networking equipment in a compact, vertical format. In some cases, computer racks are simply arranged in parallel rows. In other cases, the rows may be arranged in alternating “cold aisles” 15 and “hot aisles 10”-see FIGS. 2 and 3. In cold aisles 15, the fronts of the computer racks face each other, allowing servers to draw in cool air efficiently. Conversely, in hot aisles 10, the backs of the computer racks face each other, channeling the warm exhaust air away from the equipment. This setup facilitates the management of airflow to prevent the mixing of hot and cold air, thus enhancing cooling efficiency. Beyond this, the data center may also include areas dedicated to power supplies and backup systems, network connectivity hubs, and security monitoring stations, all designed to support the primary function of the computer racks and ensure continuous, secure operations. Cable management systems are also critical, often running beneath raised floors or above in ceiling plenums, to keep power and data cables organized and out of the way, further contributing to the operational efficiency and safety of the data center.

Effective air circulation through a computer rack is crucial for maintaining optimal operating temperatures and ensuring the longevity and reliability of the hardware. The process typically involves a carefully designed airflow management system that directs cool air to enter the computer rack from the front and warm air to exit from the back. As the cold air generally enters the front of the computer rack, it passes over the server components, absorbing heat generated by CPUs, GPUs, power supplies, and other heat-generating components. This warmed air then rises and exits through the back of the computer rack, driven by the natural process of convection or assisted by fans located within the computer rack hardware.

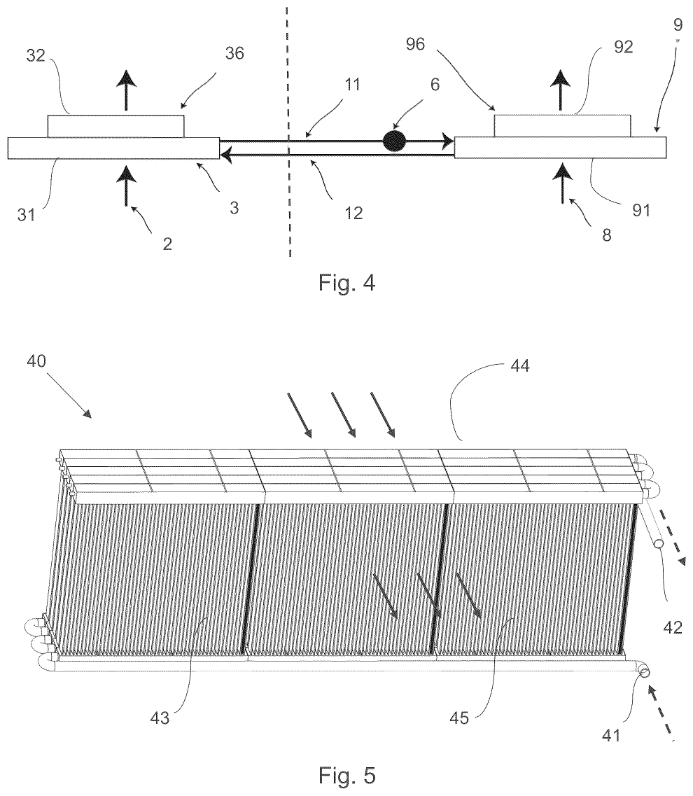

A general diagram of the air cooling portion of the pre-cooling system of the present invention is seen in FIG. 4. The system may include a first heat exchanger 9 and a second heat exchanger 3. The first heat exchanger 9 may have a first air inlet 91 and a first air outlet 92. The air may flow naturally or with the help of the air pump 96. The first heat exchanger 9 may be located and configured to accept hot air 8 coming from the back of the at least one computer rack 5, as described in more detail below. This location is depicted in FIG. 4 as being to the right of the vertical dotted line. The first air outlet 92 may be configured to release the cooler air either back into the data center, or, depending on the temperature, direct the airflow to an air conditioning unit for further cooling. A first air pump 96 may be used to increase airflow through the first heat exchanger.

A second heat exchanger 3 may also be provided, which may include a second air inlet 31 and a second air outlet 32. The second heat exchanger may be located in a cooler area, such as another area away from the computer racks 5 inside the data center or an area outside the data center, as dictated by predominant temperatures at the location of the data center. The second air inlet 31 may be configured to accept the incoming airflow 2, as seen in FIG. 4, which may be directed by the optional second air pump 36. The second air outlet 32 may be configured to exhaust the air from the second heat exchanger after causing circulating fluid within the second heat exchanger to cool down. A second air pump 36 may be used to increase air circulation through the second heat exchanger.

Heat transfer may be achieved by using a circulating fluid, such as water or a mixture of water and ethyl glycol. The fluid may be continuously or intermittently circulated between the first and second heat exchangers 9 and 3 by a fluid pump 6. In one exemplary arrangement, the cooler fluid may be pumped using the fluid pump 6 to proceed from the second heat exchanger 3 through the incoming line or lines 11 toward the first heat exchanger 9. A return fluid line or lines 12 may be provided to complete the fluid circuit and cause warmer fluid to flow from the first heat exchanger 9 to the second heat exchanger 3.

In embodiments, the circulating fluid may accept the heat from the air passing through the first heat exchanger 9, thereby cooling the incoming air 8. The fluid may then be circulated through the second heat exchanger 3 to cool it down and transfer the heat to the air flow 2 passing therethrough.

The entire cooling circuit of the present invention is simple and inexpensive to operate, as it does not deploy any refrigerant or compressed gas, as is typical of conventional air conditioners. It operates using the difference in air temperature at various locations in and out of the data center.

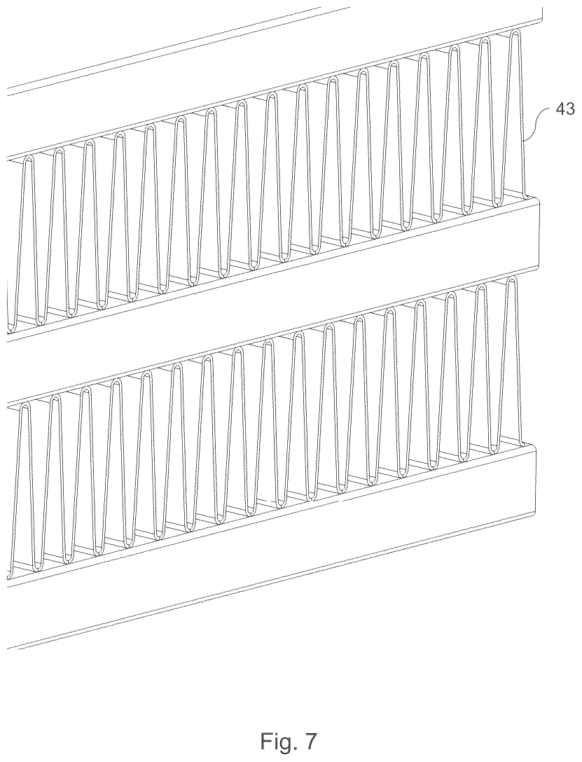

FIGS. 5 through 7 show exemplary designs of suitable heat exchangers 40 that may be used for the purposes of the present invention. Discussed herein are air-to-fluid heat exchangers, although other types of heat exchangers configured to cool down the hot air coming out of the backs of the computer racks may also be used. A typical fluid-air heat exchanger 40, often used in systems requiring the efficient transfer of heat from a fluid to air and vice versa, features a design that maximizes surface area for heat exchange while ensuring robust airflow dynamics. This design includes a plurality of fluid passages extending from the fluid inlet 41 to the fluid outlet 42 where the working fluid flows, as shown in broken line arrows in FIG. 5. Suitable examples of a fluid used in such systems are water or a water and ethyl glycol mixture. These passages are typically made from conductive materials like copper or aluminum to facilitate heat transfer. Surrounding these fluid passages are convoluted metal fins 43, intricately designed to increase the surface area available for heat exchange-see FIG. 7. The convoluted shape of these fins 43 creates a complex surface pattern that disrupts the airflow, enhancing the air's contact time with the fins and thereby improving the heat exchange efficiency.

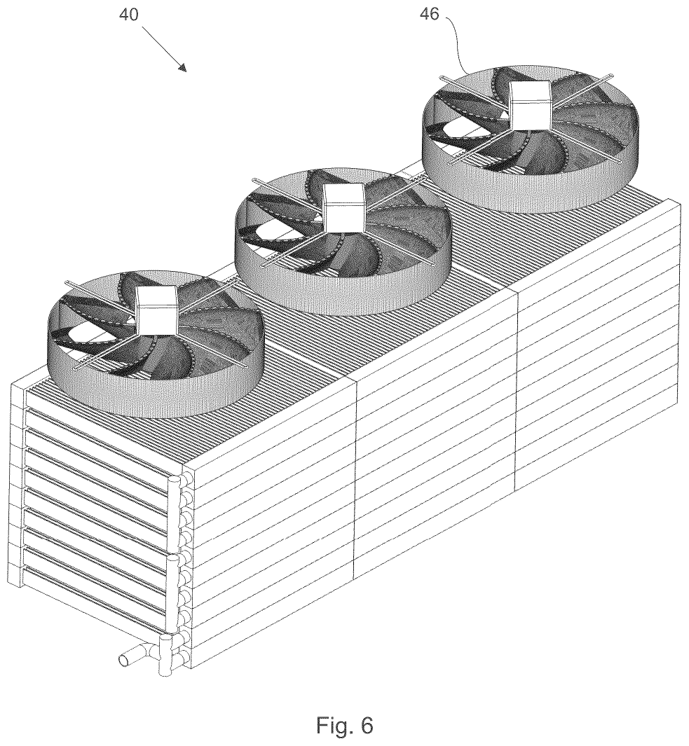

The fins 43 may be strategically positioned in the path of the airflow from the air inlet 44 to the air outlet 45, as seen in FIG. 5. The flow of air may be directed by one or more air pumps, such as fans 46, as seen in FIG. 6, or by natural convection. To cool the passing air, the airflow is directed over and through these convoluted fins 43 as it proceeds from the air inlet 44 to the air outlet 45, so that the heat is transferred from the warmer air outside the fins to the cooler fluid inside the heat-exchanging fluid passages. To cool the fluid, the opposite may be arranged, when the passing cooler air absorbs the heat from the fins, thereby cooling the fluid passing through the heat-exchanging fluid passages. This design not only maximizes the heat transfer efficiency but also optimizes the physical space, allowing for more compact heat exchanger configurations. The overall effectiveness of the heat exchanger depends on several factors, including the fin design, the flow rate of the fluid and air, and the thermal properties of the materials used. The amount of airflow needed to cool a typical computer rack in a data center can vary based on several factors including the design of the data center, the type of equipment in the rack, and the heat load generated by the equipment. However, a general guideline can be given using the cooling requirement in terms of cubic feet per minute (CFM) of air per kilowatt (KW) of heat load. Typically, data center racks, when fully loaded, can generate anywhere from 4 KW to 20 KW or more per rack. A common rule of thumb is that each kW of heat load requires approximately 150 to 200 CFM of airflow for effective cooling. For example: (i) a rack with a 10 kW load might require between 1,500 and 2,000 CFM of airflow, while (ii) a rack with a 20 kW load might require between 3,000 and 4,000 CFM of airflow.

One key innovation of the present invention is the design configured to capture hot air coming out of the back side of the at least one computer rack before it mixes up with ambient air surrounding multiple rows of computer racks. The capture of this air right after its passing over the computer components of the computer rack allows efficient precooling thereof without heating up the entire space of the data center.

The most basic configuration of the precooling system is to position the first heat exchanger 9 at the top of the at least one computer rack and over the back area thereof so that hot air coming out of the back of the computer rack can passively enter or be actively drawn into the first heat exchanger.

In other embodiments, the enclosed containment space may be defined by the at least one computer rack on at least one side thereof, a floor of the data center on a bottom thereof, a first inlet of the first heat exchanger on a top thereof. In various configurations contemplated by the present invention, one or more of the other sides of the enclosed containment space may be formed by additional computer racks, positioned next to the first computer rack or opposite thereof and spaced apart therefrom, as described below. In other embodiments, one or more physical barriers to airflow may be used, thereby forming an airflow path through the at least one computer rack and into the first air inlet of the first heat exchanger. Examples of such physical barriers to the airflow include other sides of the enclosed containment space which may be formed by at least one wall of the data center. The physical barrier may not be a permanent solid structure. In embodiments, at least one side of the enclosed containment space or a portion thereof may be formed by an openable physical barrier. Examples of an openable physical barrier may include a door, a retractable screen, a retractable curtain, or another temporary partition. Physical barriers to airflow may be constructed from fire-resistant plastic panels, glass, or metal sheets. Use of transparent materials for doors and panels may be advantageous to allow visibility and light penetration. Design of the panels forming at least some components of a containment structure may be modular, allowing for easy expansion or reconfiguration as the data center grows or changes.

In further embodiments, airflow may be directed to the enclosed containment space by air fans and other air pumps, or the air may be separated from the rest of the data center by an active air curtain, as the invention is not limited in this regard.

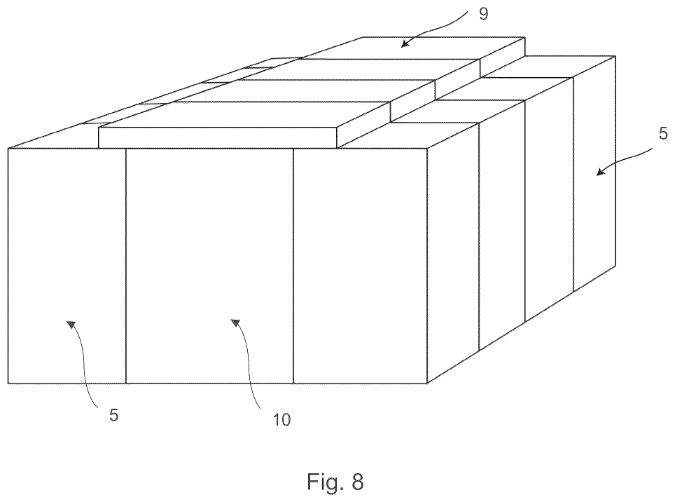

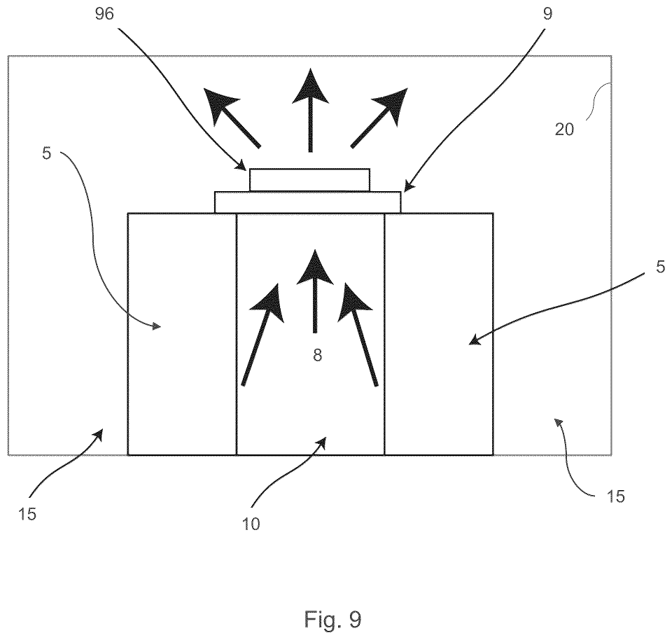

An exemplary configuration of a containment structure is seen in FIG. 8, showing a first row of computer racks 5 spaced apart from the second row of computer racks 5. The backs of the computer racks 5 face each other between the two rows thereof, while the fronts of each row of computer racks face away from each other, as is typical in an alternating “cold aisles” and “hot aisles” arrangement of the data center 20. The enclosed containment space 10 is formed between the two rows of computer racks. The sides of the enclosed space 10 may be closed off as necessary.

One or more first heat exchangers 9 may be positioned on top of the enclosed space 10 and span the distance between adjacent rows of computer racks 5. The creation of the enclosed space 10 between the backs of the computer racks 5, the floor and side walls of the data center 20, and the top cover containing one of more first heat exchangers 9 is needed to direct the air coming from the back sides of the computer racks 5 toward the air inlets of the first heat exchanger 9. In other embodiments, a dedicated physical structure of a containment structure may be created to achieve the same purpose of enclosing the space where the hot air accumulates from the back of the computer racks 5 and directing the hot air toward the air inlet of the precooling system of the present invention.

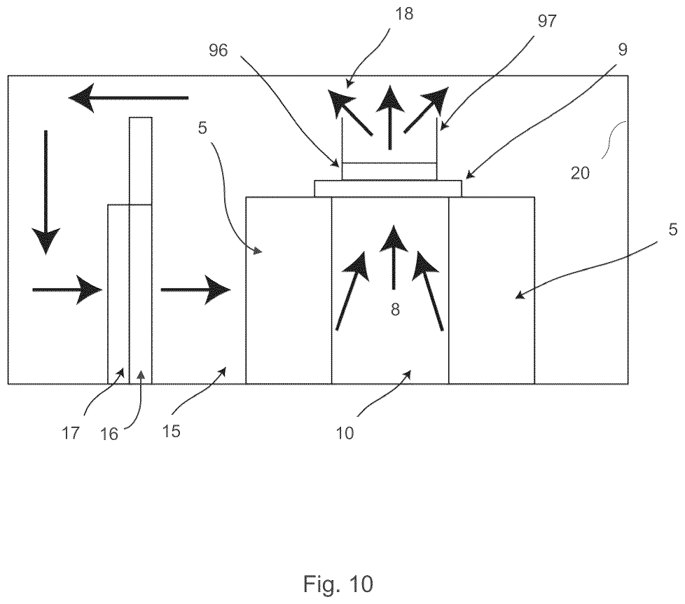

A side view of this arrangement is seen in FIG. 9 showing a first embodiment of the present invention. FIG. 9 shows how the hot air 8 at first air temperature T1 enters the enclosed space 10 and, from there, how the hot air proceeds up and into the first heat exchanger 9, optionally aided by the air pump 96. Cool air 15 at a second temperature T2 is present outside the computer racks 5. While passing through the first heat exchanger 9 of the precooling system, the air is cooled from the temperature T1 to a temperature T2 by the circulating cooler fluid and is then directed from the first air outlet to be released back into the internal space of the data center 20, where it proceeds to enter again the fronts of the computer racks 5. This air circulation may be sufficient to cool the computer components in the computer racks 5 to a desired temperature. The temperature T1 is, of course, higher than the temperature T2.

In further embodiments of the invention, the temperature of air coming out of the first air outlet may still be warmer than the required temperature T2, as the precooling system of the invention may not be sufficient by itself to cool the air to an adequate extent. In this case, the air from the first outlet of the first heat exchanger 9 may be directed to the inlet of an air conditioning system, where it may be cooled further to a desired temperature before being released back into space 15 outside the rows of the computer racks 5. The use of the precooling system of the present invention in addition to a conventional air conditioning system may reduce the need to turn the air conditioning system ON and reduce the durations of its use as the air coming into the air conditioning system would be already precooled by using the precooling system of the invention in a much more energy-efficient manner.

The system of first heat exchangers 9 may be arranged to be on top of the containment structure created for at least one computer rack 5, at least one row of computer racks 5, at least two rows of computer racks 5 as described above, or over multiple rows of computer racks 5, as the invention is not limited in this regard. Fluid from one or more first heat exchangers 9 may be directed by the fluid pump 6 to be cooled at one or more second heat exchangers 3 (not shown in FIG. 9), as described above. These one or more second heat exchangers 3 may be positioned outside the data center 20 or in other locations as described below in greater detail. The choice of positioning the second heat exchanger 3 depends on the local temperature at the location of the data center.

A controller may be provided as part of the precooling system of the present invention. The controller may be equipped with temperature sensors to monitor air and fluid temperature at various locations of the precooling system. Examples of positioning temperature sensors may include one or more locations inside the computer racks 5, the enclosed containment space 10, space 15 outside the computer racks 5, first air inlets and first air outlets of the first heat exchangers 9, second air inlets and second air outlets of the second heat exchanger 3, heat exchanging fluid passages of the first and second heat exchangers, etc.

In addition, the controller may be configured to operate various components of the precooling system with adjustable flows. Examples of such control include airflow through the first air pump 96, the second air pump 36, the fluid pump 6, and other components, as described below in greater detail. The controller may be configured to operate automatically so as to turn ON, turn OFF, and adjust the operation of the system on a time-scheduled basis or depending on the readings of various temperature sensors and/or crossing or exceeding one or more predefined temperature thresholds. Alternatively, the controller may be manually operated by a skilled operator, as the invention is not limited in this regard. Typically, the temperature inside the data center may be maintained between 18 to 27 degrees C. to provide for adequate operation of the electronic equipment.

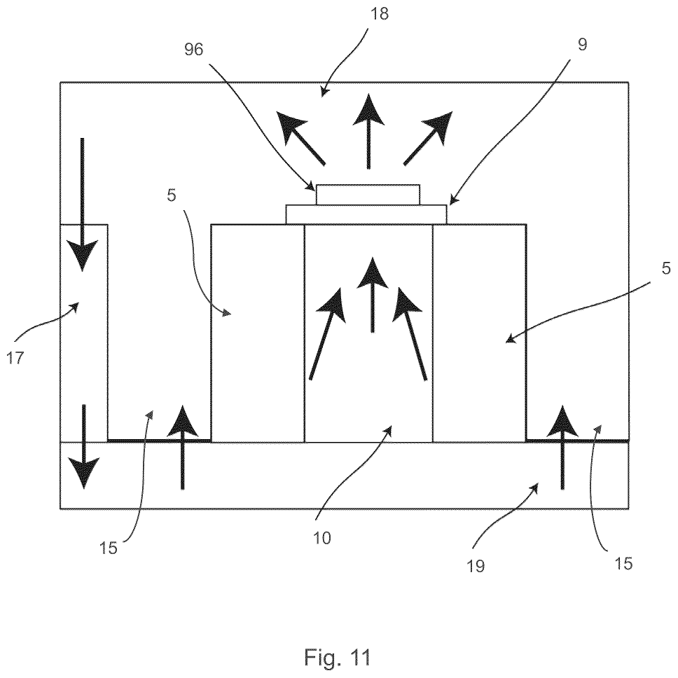

FIG. 10 shows an alternative configuration of the second embodiment of the precooling system. It may feature the same configuration of the containment structure formed between a pair of spaced apart rows of computer racks 5 with the first heat exchanger 9 positioned on top and spanning the space between thereof. The first air outlet of the first heat exchanger 9 may be located close to the ceiling of the data center 20. Alternatively, as seen in FIG. 10, it may feature dedicated ductwork such as a first duct or chimney 97 with an open top configured to raise the exhaust point of the precooled air coming out of the first heat exchanger 9 to be as high as possible.

The data center may feature a partial partition 16 located on one end thereof which may include a chiller component from the conventional air conditioning system that may be already in use at the data center 20. It may also include a fan or air pump 17 configured to move air through the chiller 16. The present invention may be used either in a no-air-conditioning mode, in which the air pump 17 may direct the cooled air coming from the ceiling plenum 18 across the partial partition and toward cold aisle space 15 for further entry into the fronts of the computer racks 5. Alternatively, or when needed, this configuration may be used in the air-conditioning mode, in which the air coming from the first outlet of the first heat exchanger may be further cooled by passing through the chiller 16. In either case, this arrangement may provide significant energy savings as compared to running the air conditioning part of the system on a continuous basis.

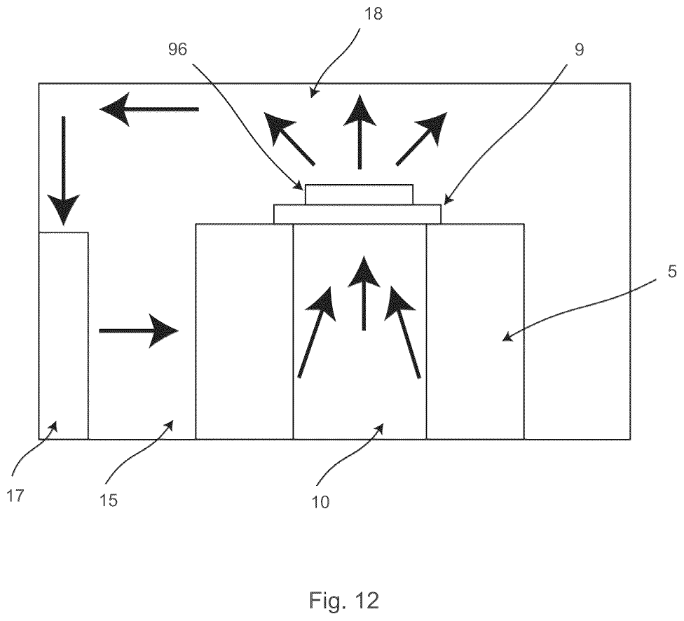

FIG. 11 shows a third alternative configuration of the precooling system of the present invention, which is applicable for data centers that have an elevated floor with a subfloor space 19 configured to release cooler air into the cold aisles 15, as shown by black arrows. In this case, the fan of the existing chiller system 17 may be used to direct the cooler air from the first outlet of the first heat exchanger 9 toward the entry into the fronts of the computer racks 5. As before, the fan 17 may be used by itself or in combination with operating the chiller of the air conditioning system, depending on the air temperatures in various parts of the data center. The chiller of the air conditioning system may be turned less frequently and for shorter periods of time as compared with a conventional system in this configuration, which only uses the chiller as the sole source of cooled air.

Furthermore, the precooling system of the present invention easily integrates with existing systems. In case of required maintenance or repairs, the precooling system may be simply turned off, while the main air cooling function is provided by the air conditioning portion of the system. Once back in operation, the precooling system may resume providing energy savings while maintaining proper operation of the computer equipment of the data center.

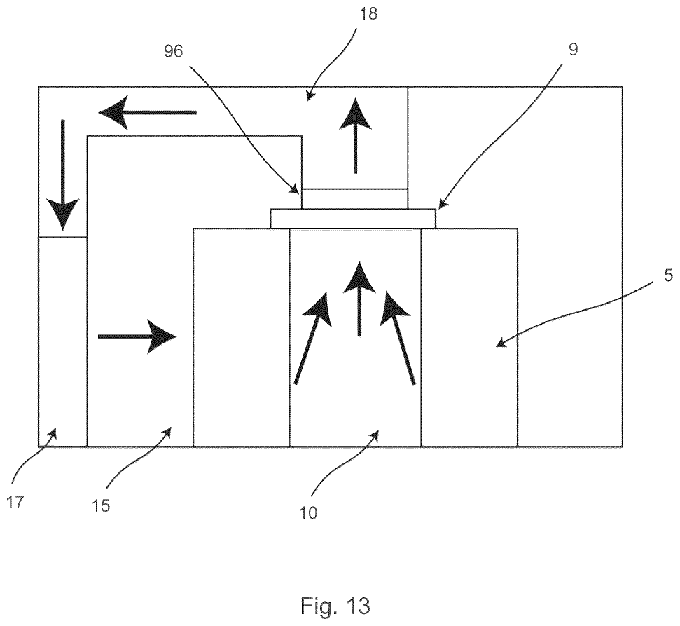

FIG. 12 shows a fourth embodiment of the invention, which has a similar configuration as in FIG. 9 but without the elevated floor. This arrangement may be referred to as a “perimeter cooling” approach to provide cool air for the data center. The air pump 17 may be used with or without the additional air cooling which may be provided by a built-in chiller of the air conditioning part of the system. The air pump 17 may be configured to circulate the cooled air coming out of the first heat exchanger outlet to be directed back to the cold aisles 15 to provide air cooling for the computer racks 5.

FIG. 13 shows a fifth embodiment of the invention in which a dedicated duct system 18 guides the cooler air from the first air outlet of the first heat exchanger 9 along the ceiling of the data center and toward the air pump 17. The air pump 17 may be configured to direct the cooler air towards the cold aisles 15 so as to maintain the air cooling of the computer equipment on the computer racks 5.

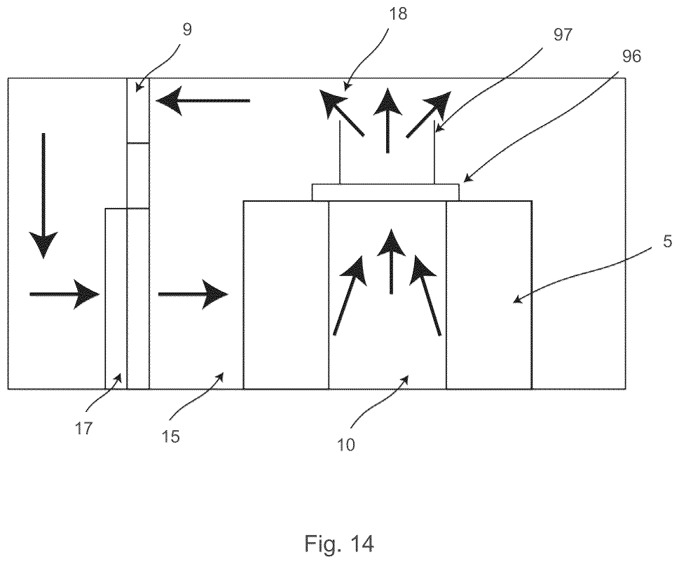

FIG. 14 shows a further, sixth embodiment of the present invention. In this embodiment, the first heat exchanger is located at the entrance point to the plenum on one side of the data center. One or multiple containment structures may be configured to direct airflow therefrom toward the ceiling plenum 18. All air collected at the plenum 18 may then be drawn into the side plenum through the first heat exchanger 9 where it is cooled before recirculation via the air pump 17, with or without a supplemental cooling through an optional chiller associated therewith.

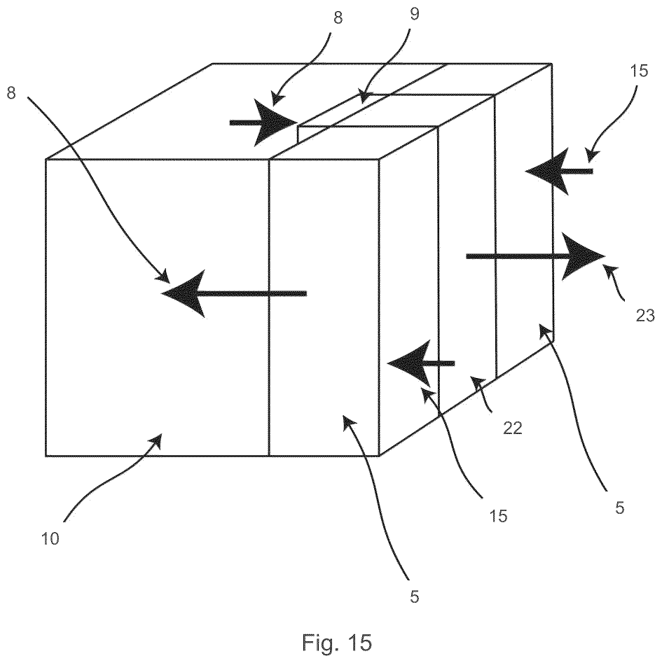

FIGS. 15 to 18 show the seventh through tenth embodiments of the present invention, with the first heat exchanger located not on top but on the side of the containment structure. In particular, FIG. 15 shows a seventh embodiment with a single row of computer racks 5 and the containment structure 10 formed by walls or additional partitions installed for that purpose. The top is not seen for clarity but is assumed to be in place to prevent the warm air from leaving the containment structure 10. The cold air from the cold space 15 may be drawn into the containment structure 10 forming a warm air 8 after air cooling of the computer equipment inside the computer racks 5. The first heat exchanger 9 may be positioned on a side at the exit of the containment structure into space 22. It may be configured to precool the warm air 8 to form a cool air 23 on the side of the first air outlet of the first heat exchanger 9. In embodiments, the first heat exchanger 9 may be used as a precooler for an air handling unit (AHU) that may be positioned to take the outlet air of the first air outlet of the heat exchanger 9 as the inlet air to the AHU. The optional AHU is not shown in the drawing, but may be positioned where number 22 is pointing.

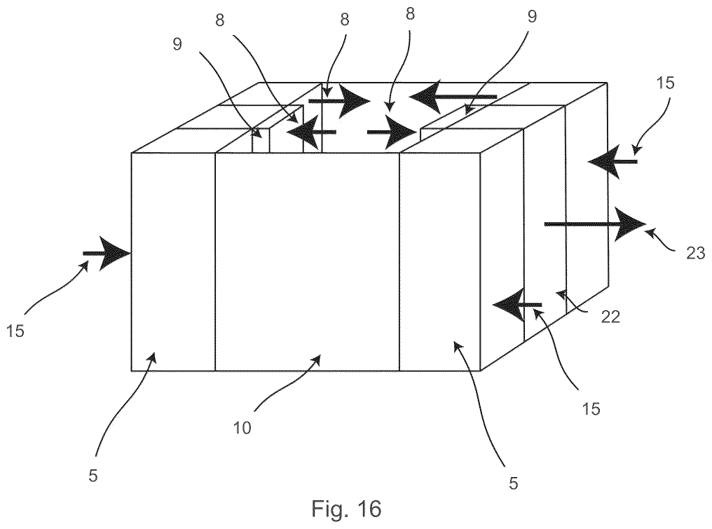

Another version of the concept of positioning the first heat exchanger on the side of the containment structure is seen in FIG. 16, showing an eighth embodiment of the invention. Two spaced apart rows of computer racks 5 are seen with the walls or partitions forming the remaining portion of the containment structure 10. A top cover is removed in this figure also but is presumed to be present for proper operation. Cold air from cold aisle 15 is seen entering the fronts of computer racks 5 on both sides of the containment structure 10. Two symmetrical first heat exchangers, 9, are seen to be positioned on two opposite sides of the containment structure and are configured to cool the passing warm air 8 to a lower temperature before releasing it into the data center as a cool stream of air 23, proceeding via passages 22. As mentioned in the description of the previous embodiment, the first heat exchanger 9 may be used as a precooler for an AHU that may be positioned to take the outlet air of the first air outlet of the heat exchanger 9 as the inlet air to the AHU. The optional AHU is again not shown in the drawing, but may be positioned where number 22 is pointing.

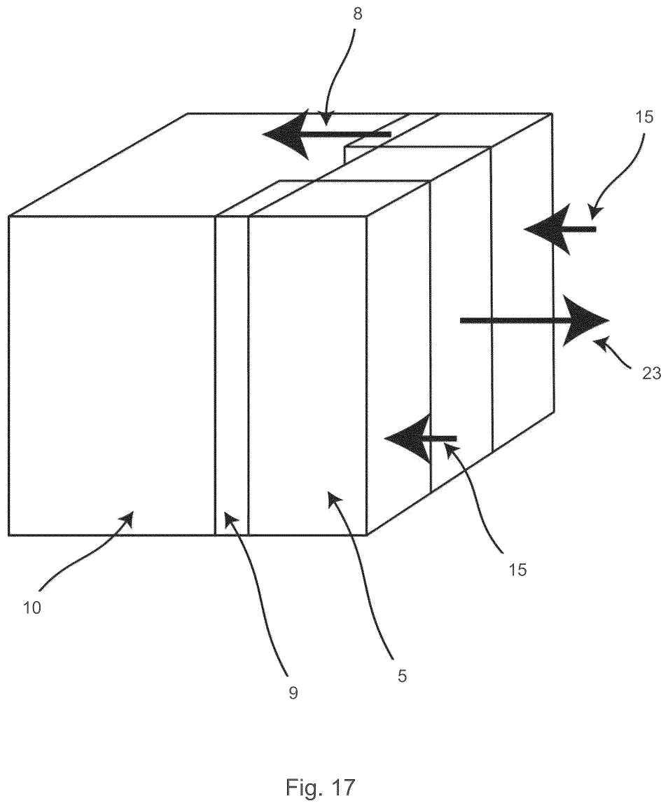

A ninth embodiment is shown schematically in FIG. 17. In this case, each computer rack 5 is equipped at the back side with a dedicated first heat exchanger 9. Warm air coming out of the back side of each computer rack 5 is immediately cooled before entering the containment structure 10. Cooled air may be mixed in the containment structure 10 from two or more computer racks 5 and allowed to pass back into the data center, or alternatively, it may be directed for further cooling in the air conditioning system of the data center 20. An optional AHU may be positioned at the first air outlet of the first heat exchanger 9. In this case, the air flow 23 would come out of the AHU, which would further cool the precooled air in the containment structure 10.

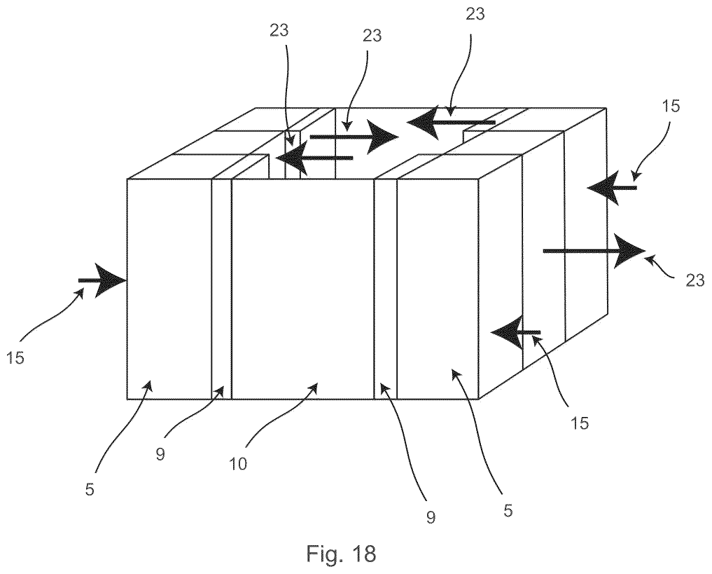

Finally, FIG. 18 shows a tenth embodiment of the invention, in which two spaced apart rows of computer racks 5 form a containment structure 10. Each computer rack 5 may feature a dedicated first heat exchanger 9 positioned on the back side thereof. Cooled air 23 may be collected in the containment structure 10 and directed either back into the data center or toward additional cooling using refrigeration units of the data center. Similarly to what is mentioned above, two optional AHUs may be positioned at the first air outlet of each first heat exchanger 9 in opposite rows, each placed in the center of the row of computer racks 5. In this case, the air flow 23 would come out of the AHU, which would further cool the precooled air in the containment structure 10.

In additional contemplated embodiments, the data center itself may be used as a container structure with the first heat exchanger located inside the data center and the second heat exchanger located outside thereof. In this case, the precooling system may include a first heat exchanger with a first air inlet configured to accept air coming out of the at least one computer rack, and a first air outlet configured to release air into an ambient environment of the data center and to enter into the at least one computer rack. As before, the first heat exchanger may also include a first plurality of fluid circulation passages configured to extract heat from the air passing from the first air inlet to the first air outlet into a fluid circulating therethrough.

The second heat exchanger, in this case, may include a second air inlet configured to accept air outside the ambient environment of the data center, and a second air outlet configured to exhaust air also outside the ambient environment of the data center. As before, the second plurality of fluid circulation passages may be provided and configured to extract heat from and, thereby, cool the fluid circulating therethrough.

The precooling system may also include a fluid pump configured to circulate the fluid between the first plurality of fluid circulation passages of the first heat exchanger and the second plurality of fluid circulation passages of the second heat exchanger to cause heat transfer from the air inside the data center to the air outside thereof.

It is contemplated that any embodiment discussed in this specification can be implemented with respect to any method of the invention, and vice versa. It will be also understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference. Incorporation by reference is limited such that no subject matter is incorporated that is contrary to the explicit disclosure herein, no claims included in the documents are incorporated by reference herein, and any definitions provided in the documents are not incorporated by reference herein unless expressly included herein.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), propertie(s), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12, 15, 20 or 25%.

All of the devices and/or methods disclosed and claimed herein can be made and executed without undue experimentation in light of the present disclosure. While the devices and methods of this invention have been described in terms of preferred embodiments, it will be apparent to those of skill in the art that variations may be applied to the devices and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A precooling system for a data center, wherein the data center comprises an enclosure with a containment structure located therein, wherein the containment structure, in turn, comprises at least one computer rack configured to pass air therethrough and an enclosed containment space, the precooling system comprises:
a first heat exchanger with a first air inlet configured to accept air flowing from the enclosed containment space, a first air outlet, and a first plurality of heat-exchanging fluid passages configured to extract heat from and, thereby, cool the air passing from the first air inlet to the first air outlet, wherein the heat is extracted into the fluid circulating therethrough,
a second heat exchanger with a second air inlet configured to accept air outside the containment structure, a second air outlet configured to exhaust air outside the containment structure, and a second plurality of heat-exchanging fluid passages configured to extract heat from and, thereby, cool the fluid circulating therethrough, and
a fluid pump configured to circulate the fluid between the first heat exchanger and the second heat exchanger,
wherein the containment structure is configured to allow air to flow from the enclosed containment space into the first air inlet of the first heat exchanger,
wherein the enclosure of the data center is configured to allow air from the first air outlet of the first heat exchanger to be directed toward and through the at least one computer rack, thereby air-cooling thereof, before flowing into the enclosed containment space.

2. The precooling system for a data center, as in claim 1, wherein the first heat exchanger further comprises a first air pump configured to cause air to pass from the first air inlet to the first air outlet.

3. The precooling system for a data center, as in claim 1, wherein the second heat exchanger further comprises a second air pump configured to cause air to pass from the second air inlet to the second air outlet.

4. The precooling system for a data center, as in claim 1, wherein the first heat exchanger is positioned to facilitate the first air inlet to capture air from the containment structure, thereby facilitating cooling thereof while passing therethrough.

5. The precooling system for a data center, as in claim 4, wherein the first heat exchanger is located above or on a side of the enclosed containment space with the first air inlet configured to accept air therefrom.

6. The precooling system for a data center, as in claim 4, wherein the data center comprises a ductwork configured to direct air from the containment structure to the first air inlet of the first heat exchanger.

7. The precooling system for a data center, as in claim 6, wherein the ductwork comprises a chimney configured to direct air from the containment space toward a ceiling of the data center.

8. The precooling system for a data center, as in claim 1, wherein the data center comprises two spaced apart rows of computer racks with backs of computer racks in each of the two rows facing each other and, together with the first heat exchanger positioned on top and bridging a gap between two rows of computer racks, forming the enclosed space for accepting the air passing through the computer racks on both sides thereof.

9. The precooling system for a data center, as in claim 1, wherein the first outlet of the first heat exchanger is configured to direct airflow to an air conditioning system for additional cooling after passing through the first heat exchanger.

10. The precooling system for a data center, as in claim 1, further comprising a controller equipped with a plurality of temperature sensors configured to monitor air temperature in the at least one computer rack, as well as before and after passing through the first heat exchanger.

11. The precooling system for a data center, as in claim 10, wherein the controller is configured to initiate, terminate, or adjust the operation of the precooling system depending on the temperature reading throughout thereof or on a time-scheduled basis.

12. The precooling system for a data center, as in claim 1, wherein the enclosed containment space is defined by the at least one computer rack on at least one side thereof, a floor of the data center on a bottom thereof, a first inlet of the first heat exchanger on a top or a side thereof, and wherein other sides of the enclosed containment space are formed by other computer racks or by one or more physical barriers to airflow, thereby forming an airflow path through the at least one computer rack and into the first air inlet of the first heat exchanger.

13. The precooling system for a data center, as in claim 12, wherein other sides of the enclosed containment space are formed by at least one wall of the data center or at least one more computer rack.

14. The precooling system for a data center, as in claim 12, wherein each computer rack is associated with a first heat exchanger, wherein airflow from each computer rack is passed through the first heat exchanger for precooling purposes.

15. The precooling system for a data center, as in claim 12, wherein at least one side of the enclosed containment space is formed by an openable physical barrier.

16. The precooling system for a data center, as in claim 15, wherein the openable physical barrier is a door, a screen, a curtain, or a temporary partition.

17. A precooling system for a data center with at least one computer rack, the precooling system comprises:
a first heat exchanger with a first air inlet configured to accept air coming out of the at least one computer rack, a first air outlet configured to release air into an ambient environment of the data center and to enter into the at least one computer rack, and a first plurality of fluid circulation passages configured to extract heat from the air passing from the first air inlet to the first air outlet into a fluid circulating therethrough,
a second heat exchanger with a second air inlet configured to accept air outside the ambient environment of the data center, a second air outlet configured to exhaust air outside the ambient environment of the data center, and a second plurality of fluid circulation passages configured to extract heat from and, thereby, cool the fluid circulating therethrough, and
a fluid pump configured to circulate the fluid between the first plurality of fluid circulation passages of the first heat exchanger and the second plurality of fluid circulation passages of the second heat exchanger.
